(19) United States
(12) Patent Application Publication
(10) Pub. No.: US 2019/0324075 A1
(43) Pub. Date: Oct. 24, 2019

(54) MONITORING SERVICE CURRENT FOR ARC FAULT DETECTION IN ELECTRICAL BRANCH CIRCUITS

(71) Applicant: James J. Kinsella, Brentwood, TN (US)

(72) Inventor: James J. Kinsella, Brentwood, TN (US)

(21) Appl. No.: 16/503,579

(22) Filed: Jul. 4, 2019

Related U.S. Application Data
(63) Continuation-in-part of application No. 14/037,922, filed on Sep. 26, 2013, now abandoned.

(51) Int. Cl. G01R 31/12; H02H 1/00; H01F 38/30; G01R 31/02; G01R 15/18

(52) U.S. Cl. CPC G01R 31/1272; H02H 1/0007; H01F 2038/305; G01R 31/025; G01R 15/183; H01F 38/30

(57) ABSTRACT

An RM current sensor assembly is used to indirectly sense the service current being drawn from a service by an electrical branch circuit, the output from which can be used to monitor the service current for features indicative of the presence series and/or parallel arc faults are present in the electrical branch circuit as they progress from their incipiency. The RM current sensor assembly is significantly smaller and less costly than prior art current transformers sensing current directly from the service line at full magnitude. The requisite bandwidth for accurately performing extraction of features indicating arc faults is maintained at this low cost and size because the amount of current actually sensed is substantially smaller. Current signature analysis can also be performed to monitor the operational integrity of appliances with motors, and an RM differential current sensor can detect cumulative leakage current to ground in the electrical branch circuit. All of the processing can be performed by a smart meter.

### CROSS-REFERENCE TO RELATED APPLICATIONS

This application claims priority as a continuation-in-part of U.S. application Ser. No. 14/037,922, filed Sep. 26, 2013 and titled “RATIO METRIC CURRENT MEASUREMENT,” and which is incorporated herein in its entirety by this reference.

This Application is related to U.S. patent application Ser. No. ______, titled “A REDUCED COST RATIO METRIC MEASUREMENT TECHNIQUE FOR TARIFF METERING AND ELECTRICAL BRANCH CIRCUIT PROTECTION,” filed concurrently herewith, and which is incorporated herein in its entirety by this reference.

### FIELD OF THE INVENTION

The invention generally relates to fault detection in electrical branch circuits, and more particularly to the holistic monitoring of metered service current at the smart meter level to detect the existence of arc faults to preempt fires.

### BACKGROUND OF THE INVENTION

According to a 2017 research report published by the National Fire Protection Association (NFPA), in the United States alone, there were an estimated 45,210 home structure fires in 2010-2014 involving electrical failure or malfunction. U.S. fire departments responded to an estimated annual average of 31,960 reported non-confined home structure fires involving electrical distribution or lighting equipment in 2010-2014. In that time-period, these fires resulted in 400 civilian fire deaths, 1,180 civilian fire injuries, and $1.2 billion in direct damage. An additional estimated annual average of 14,760 non-confined non-home fires in the U.S. resulted in 20 civilian deaths, 190 civilian injuries, and $659 million in direct property damage each year over this period.

Fires due to electrical malfunction can have a number of different origins. They can be caused by an equipment malfunction, an overloaded circuit or extension cord, from faulty insulation of wiring, mechanical and electrical stress caused by overuse, over-currents, lightning strikes, loose connections, and excessive mechanical damage to insulation and wires that can lead to arcing. When the type of failure or malfunction could be determined for the fires reported above, some form of arcing was most often involved in these fires. Often, these short circuit arcs result from defective or worn insulation. Other common sources for arcing events include an arc or spark from operating equipment, faulty contacts or broken conductors, short circuit arcs resulting from mechanical damage, and arcs caused by water.

Fault detection schemes have long been commonly employed in the electrical branch circuits of homes and business structures at the branch level to detect short-circuit faults (e.g. such as when water or metal completes a circuit outside of the intended circuit). Devices such as ground fault circuit interrupters (GFCIs), residual current devices (RCDs), circuit breakers and fuses are used to detect these types of ground faults. Generally, when these faults occur, very large currents tend to flow that are easy to detect and act upon to interrupt the fault and resolve it. The devices mentioned above are designed to interrupt this large current flow at the individual branch level of an electrical distribution system to prevent harm to people and equipment connected to the faulty branch. This also makes it possible to isolate the fault in the affected branch, without interrupting current to the other branches of the branch circuit. In contrast, arcing faults can manifest very little current at their incipiency but can still ignite fires long before the arcing current becomes significant enough to be detected by the previously described devices.

There are two general types of these arcing faults that can occur: series and parallel. The magnitude of the arc current depends on whether the fault is substantially a series or a parallel one. Both types of faults can occur when, for example, a nail is driven into the wall and accidentally passes through or otherwise weakens the insulation of an electric wire or cable. The damage to the wires within can cause electricity to leap a very small gap (a series fault), or to flow to another conductor (e.g. ground) through the damaged insulation, leading to thermal increases that are capable of igniting combustible materials.

When a single wire is badly damaged and creates a series arc fault (e.g. from a nail being driven into a wall), any remaining strands typically burn out because they cannot withstand the load current. This can lead to a complete break in the wire, with the nail forming a high resistance poorly connected path through the gap. The load current will then arc across the resulting gap in the wire. When the arc occurs directly across the gap, such accidental arcing is just like intentional arcing with an arc-welder. While the resulting current magnitude is small, arcing nevertheless results in very high temperatures that can exceed 10,000° F. These high temperatures can ignite nearby combustible materials, potentially resulting in house fires leading to fatalities, injuries and high property damage and loss.

The partial discharge for parallel faults results from leakage current traveling in a series of arcs through the dielectric to ease its passage through the insulation. Initially it may show up as a decrease in the insulation bulk resistance. Whether in insulation or across surfaces, long-present partial discharge (arcing) typically precedes breakdown, this serves to degrade the insulators and metals nearest the voltage gap. Leakage current eventually generates the small arcs in the form of a partial discharge that heat and gradually carbonize the insulation. Ultimately the partial discharge chars through a channel of carbonized material that conducts current across the gap. Eventually the arcs can ignite the carbonized insulation. Burnt or carbonized, insulation acts like fuel that can be ignited by electric arcs and establishes a fast-accelerating chain reaction between the leakage current generating arcs that carbonize the insulation, and the increasing carbon deposits forming on the insulation leading to an increasingly better conducting path. The cycle of arcing and carbon conduction gathers pace and intensity over time until the carbonized insulation spontaneously combusts.

True series and parallel arcing faults manifest differently than do the continuous types of ground and short-circuit faults detected by the devices listed above. Not only are the magnitudes of these currents significantly smaller (especially at their incipiency), they are also intermittent. However, they do produce observable characteristics that can be used to detect these specific types of fault and permit proper discrimination between the two. The presence of broadband noise during arc faults is a key differentiator. These high frequencies diminish as the amount of current through the series arc fault increases. This is because as the high frequency information results from its initially intermittent current flows. The longer the current flows, it can form an alternate path by carbonizing the insulation. This establishes a more consistent flow that eliminates the higher frequency information when it is mostly flowing over a gap. This makes it more effective to identify a series arc fault at its incipience, as the continuous current will never look like an abnormal current.

A parallel arc current in the form of partial causes momentary high-frequency current spikes that ride on the AC service current waveform being supplied to the branch circuit. An exemplary waveform illustrating this is effect on the service current waveform is shown in FIG. 9. Although these current spikes may not result in immediate catastrophic breakdown of the insulation at their incipiency, they do indicate that a problem with the insulation exists that could degrade sufficiently over time to create a safety issue in the form of a significant leakage current between conductors at a later date.

Series arc faults are known to cause 3, 5 and 7 harmonics to appear in the service current waveform. The observable effect of series arc faults on the service current is illustrated in FIGS. 8A and 8B. The service current will continue to flow only slightly diminished by the arc voltage and will not be detected as current abnormalities by standard fault detection components until they have become much more significant and dangerous. That is because those components are not intended to trip until the resulting current has far exceeded a magnitude at which combustion can take place.

Notwithstanding the foregoing, monitoring service current at the metering level to identify and discriminate these arc faults at their incipiency (i.e. before they can become a significant fire hazard), is not presently performed. Rather, they are only performed as a single instance test that provides information for that one moment in time. One type of test, known as a HIPOT (high potential) or dielectric withstand test, can be performed on a component, product or electrical branch circuit to determine the effectiveness of its insulation. The test applies extreme voltages, either between mutually insulated wires or insulated wires to electrical ground. These arcing faults are mostly observed where weakness in the insulation breaks down while the wiring is being severely stressed by the extreme voltages. Dielectric stress is expressed as volts per unit thickness.

The insulation breakdown that results from the extreme voltage applied during a HIPOT test will manifest itself at lower system level voltages as it deteriorates over time and temperature to the point where dielectric stress reaches a breakdown level. The HIPOT test is an attempt to accelerate and expose this weakness before it can cause fire hazards while in service. While this test may be effective for testing the condition of an electrical branch circuit at a moment in time, it does not monitor for such deterioration over time unless periodic testing is performed. Moreover, this type of test is not practicable for the hundreds of millions of premises in the world. People will not typically pay for such a test, especially because it does not ensure that arcing faults will not develop any time in the near future. Moreover, HIPOT testing the existing wiring in a home or business would require everything to be disconnected to avoid damaging load devices.

Another test that is also performed as a snapshot test can be performed manually on the electrical branch circuit of a premises by a technician. This test detects the presence of partial discharge based on the same observable effects on the service current as discussed above to identify parallel arc faults. The technician clamps a large and expensive current transformer (the transformer must be large to sense the large magnitude service current while maintaining the requisite bandwidth) onto the main service line(s) supplying the premises. The sensed current then analyzed for high frequency information that would indicate the presence of more parallel arc faults are present in the electric branch circuit. The technician turns off all of the circuit breakers, and then closes one branch at a time until the branch that supplies the high frequency signal is isolated. A high frequency detector is then used to sniff the isolated branch to find the location of the parallel detector so that it can be repaired. Again, this test is only good for the moment in time at which it is performed, and very few premises will ever be tested in this manner.

Recently, series arc fault detection is being provided in devices that are located at the branch level of the electrical branch circuit, similar to GFCIs. These Arc Fault Circuit Interrupter (AFCI) devices are placed at the branch circuit level to detect fault current created by partial discharge. They attempt to discriminate between arc currents caused by, for example, turning lights or other switches on and off (which are expected and safe) and those caused by partial discharge as described above due to parallel arc faults. These devices are expensive and are typically limited to only those most sensitive branches such as those supplying service to bedrooms.

Moreover, AFCIs are notoriously known for nuisance tripping, because they don't always discriminate very well between partial discharge and arc currents caused by switches or other sources that do not present a fire hazard. Because these devices are designed to open the circuit based on some threshold being exceeded, they are notorious for nuisance tripping. Nuisance tripping can be a real problem that can cause all kinds of problems, such as spoilage of food when the branch feeding a refrigerator has been interrupted when no one is home. There is a clear conflict between establishing a threshold that protects against all potentially dangerous conditions and providing a threshold that will not be tripping open the circuit when it should not be.

Clearly, it is more desirable to detect these arc fault currents at their incipiency, rather than after they have become an imminent fire hazard requiring the circuit be opened to avoid the danger. A smart meter that is provided with the appropriate signal information can, with the luxury of more time, gather analyze the data and more readily determine whether the high frequency information is just some random operation of a switch or an appliance as opposed to a developing arc fault. This would allow all premises to be monitored for these faults at the metering level of the service current to diagnose them at their incipiency as part of an overall wellness program. This has been hindered primarily by the size and cost considerations of providing such information heretofore requiring a high current, high bandwidth current transformer as a current sensor.

### SUMMARY OF THE INVENTION

In one aspect of the invention, a ratio metric (RM) sensor assembly senses a service current being drawn from an electrical service through a service line by an electric branch circuit to support real-time monitoring of the electrical integrity of the electrical branch circuit and one or more load devices coupled thereto. The RM sensor assembly includes an RM current sensor assembly that has a current divider formed of a low impedance conductor, where the low impedance conductor is configured to be conductively coupled in series with the service line carrying the service current to the electrical branch, and a higher impedance conductor coupled at two points along the lower impedance conductor. The current sensor assembly further includes a current transformer having a toroidal core through which the higher impedance conductor is fed as a primary winding, and a secondary formed of one or more windings about the core and coupled to a burden resistor that is coupled to the secondary. The RM current sensor assembly is configured to produce a sensed current output across the burden resistor, the sensed current output having a predetermined operational range of magnitude that is proportionally related to the sensed service current over the predetermined operational range of the service current. The sensed current output of the current sensor assembly is coupled to a smart meter, the sensed current output supporting the monitoring for the presence of an arc fault in the electrical branch circuit by the smart meter.

In an embodiment, the arc fault is a series arc fault.

In another embodiments, wherein the arc fault is a parallel arc fault.

In another embodiment, an electronic message is sent by the smart meter over a network to notify the service when the presence of the arc fault has been detected.

In still another embodiment, the RM sensor assembly also includes an RM differential current sensor assembly having a first current divider formed of a low impedance conductor configured to be coupled in series with the service line, and a first higher impedance conductor coupled at two points along the lower impedance conductor, and a second current divider formed of a low impedance conductor configured to be coupled in series with a neutral line by which the service current is returned to the service, with a second higher impedance conductor coupled at two points along the lower impedance conductor. The RM differential current sensor assembly also includes a differential current transformer having a toroidal core through which the first and second higher impedance conductors are fed as primary windings, and a secondary formed of one or more windings about the core and coupled to a burden resistor that is coupled to the secondary. The RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit, and the sensed differential current output is coupled to the smart meter, the sensed differential current output supporting detection of cumulative leakage current to ground in the electrical branch circuit by the smart meter.

In a further embodiment, an electronic message is sent by the smart meter over a network to notify the service of the cumulative leakage that has been detected.

In yet another embodiment, the sensed current output is used to support current signature analysis to monitor proper operation of the one or more load devices.

In a further embodiment, the sensed current output is also used by the smart meter to, within a predetermined degree of accuracy, support a determination of the power consumption based on an aggregation of the service current drawn by the electrical branch circuit over a predetermined period of time, and if the actual proportionality is not within the predetermined degree of accuracy substantially over the predetermined range of service current, performing at least a first calibration whereby at least the burden resistor is adjusted in value so that for at least one magnitude of the service current range, the sensed current output is equal to an expected magnitude within the predetermined degree of accuracy.

In another aspect of the invention, smart meter analyzes the service current drawn through a service line from an electrical service to provide real-time monitoring of electrical integrity of the electrical branch circuit. The RM current sensor assembly includes an RM sensor assembly coupled in series with the service line. The RM current sensor assembly includes a current divider formed of a low impedance conductor configured to be conductively coupled in series with the service line carrying the service current to the electrical branch, and a higher impedance conductor coupled at two points along the lower impedance conductor. The RM current sensor assembly further includes a current transformer having a toroidal core through which the higher impedance conductor is fed as a primary winding, and a secondary formed of one or more windings about the core and coupled to a burden resistor that is coupled to the secondary. The RM current sensor assembly is configured to produce a sensed current output across the burden resistor, the sensed current output having a predetermined operational range of magnitude that is proportionally related to the sensed service current over the predetermined operational range of the service current.

The smart meter also includes an analog front (AFE) configured to receive the sensed current output, the AFE configured to sample the sensed current output at a predetermined rate and convert the samples into digital values and a processor system for monitoring the sensed output current for the presence of arc faults in the electrical branch circuit, the processor system extracting features from the digital values of the sensed current output that indicates the presence of an arc fault.

In another embodiment, the RM sensor assembly of the smart meter further includes a differential current sensor assembly having a first current divider formed of a low impedance conductor configured to be coupled in series with the service line, and a first higher impedance conductor coupled at two points along the lower impedance conductor, and a second current divider formed of a low impedance conductor configured to be coupled in series with a neutral line by which the service current is returned to the service, and a second higher impedance conductor coupled at two points along the lower impedance conductor. The differential current sensor assembly also has a differential current transformer including a toroidal core through which the first and second higher impedance conductors are fed as primary windings a toroidal core through which the first and second higher impedance conductors are fed as primary windings. the RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit. The sensed differential current output is coupled to the AFE, the AFE configured to sample the sensed current output at a predetermined rate and convert the samples into digital values. The processor system uses the digital sampled of the sensed differential current output to detect cumulative leakage current to ground in the electrical branch circuit.

In a still further embodiment, the digital samples of the sensed current output are also used to determine power consumption based on a cumulative service current drawn by the electrical branch circuit over a predetermined period of time. The actual proportionality of the current sensor assembly is calibrated whereby at least the burden resistor has been adjusted in value so that for at least one magnitude of the service current range, the sensed current output is equal to an expected magnitude within the predetermined degree of accuracy.

### BRIEF DESCRIPTION OF THE DRAWINGS

FIG. 1 is an illustration of a typical split phase (or “three-line, single-phase”) electric power service commonly deployed in the United States for residential electric service;

FIG. 2 is a block diagram illustration of a prior art smart meter implemented to meter current as consumed energy for the electrical service of FIG. 1, and which illustrates the presence of ground faults, as well as series and parallel arc faults, in the branch circuit of the residence to which the service of FIG. 1 is coupled;

FIG. 3 is a simplified block diagram of the typical prior art current sensors and divider circuit used to provide the analog inputs required by the smart meter of FIG. 2 to calculate the total energy consumed from the electrical service for metering purposes;

FIG. 4 is a circuit diagram illustrating an RM current sensor of the invention that employs a ratiometric current measurement technique of the invention, and which can be used to directly supply the smart meter of FIG. 2 in lieu of the prior art sensors of FIG. 3;

FIG. 5 is a circuit diagram of a differential current sensor of the invention that employs two of the ratio metric current sensors of FIG. 4 to detect leakage current in the electric branch circuit coupled to the residential service of FIGS. 1 and 2;

FIG. 6 is a block diagram illustrating the use of the RM current sensor and RM differential sensors of the invention to enable holistic monitoring of the branch circuit by analyzing the service current at the smart meter level for progressive faults;

FIG. 7 is a circuit level block diagram of the RM current sensor assembly and the RM differential circuit sensor as deployed in FIG. 6;

FIG. 8 is a time domain diagram illustrating the manifestation on the service current waveform of partial discharge due to a weakened or impure insulation surrounding wiring in the electric branch circuit of FIG. 6;

FIG. 9A is a time domain representation of the manifestation of series arcing on the service current waveform due to a gap or damage in the wiring in the electric branch circuit of FIG. 6;

FIG. 9B is a frequency domain representation of the manifestation of series arcing on the service current waveform due to a gap or damage in the wiring in the electric branch circuit of FIG. 6; and

FIG. 10 is a block diagram representation of the use of the RM current sensor and RM differential transformer of the invention to perform holistic monitoring of the health of an electrical service and electric branch circuit of a premises at the smart meter level to enable early detection of faults in the branch circuit before they become catastrophic.

### DETAILED DESCRIPTION

Measuring current with the accuracy required for supporting the electronic metering of power consumption, while maintaining reasonable cost and compatibility with digital smart meter circuits, presents significant challenges when employing well-known prior art current sensing technologies. These well-known techniques necessitate undesirable design tradeoffs between cost, size, unnecessary power dissipation, processing compatibility and performance. Accuracy of the current measurement is important not only to ensure accurate billing of consumers, but it is also critical to the integrity of any post-processing use of the sensed information. This post-processing can control the distribution of the service, as well as monitoring the health of each consumer's electrical branch circuit, including the health of the dielectric isolation of the wiring itself.

Embodiments of a ratiometric (RM) current sensing method, sensor assembly and differential sensor assembly are disclosed that can replace known prior art sensors and differential amplifiers to measure current in support of electronic metering functions including monitoring for the incipiency of arc faults before they become a potential fire hazard. The various embodiments of the invention leverage a ratiometric design to significantly reduce the size, and complexity (and ultimately the cost) of sensing the current to support these functions at the metering level of the service current, while maintaining if not improving the required accuracy of the measurement information over a wider bandwidth and over the full range of the large magnitude service current to be measured.

Embodiments of the RM current sensor assemblies enable accurate (yet low cost) measurement of the line current, not only for accurately determining power consumption, but maintaining the requisite bandwidth to enable the cost-effective implementation and performance of various other desirable diagnostic and wellness functions including the detection of arc faults at their incipiency, rather than detecting them at the branch level when the current magnitudes resulting therefrom are already past the point where they have become dangerous. Alerts can be issued both visually and electronically by the smart meter to indicate that such currents have been detected at the earliest point of their existence as possible. This early diagnosis can provide an advanced warning that the wiring for the electrical branch circuit should be examined to locate the source of the arcing current before it becomes more dangerous. This also enables the smart meter to accumulate information regarding the arcing current as the condition advances, so that the alerts can be ramped up in urgency as the condition advances to a more critical state. The smart meter could also be programmed to shut down the service at the main breaker to the branch circuit should a critical threshold of advancement be reached.

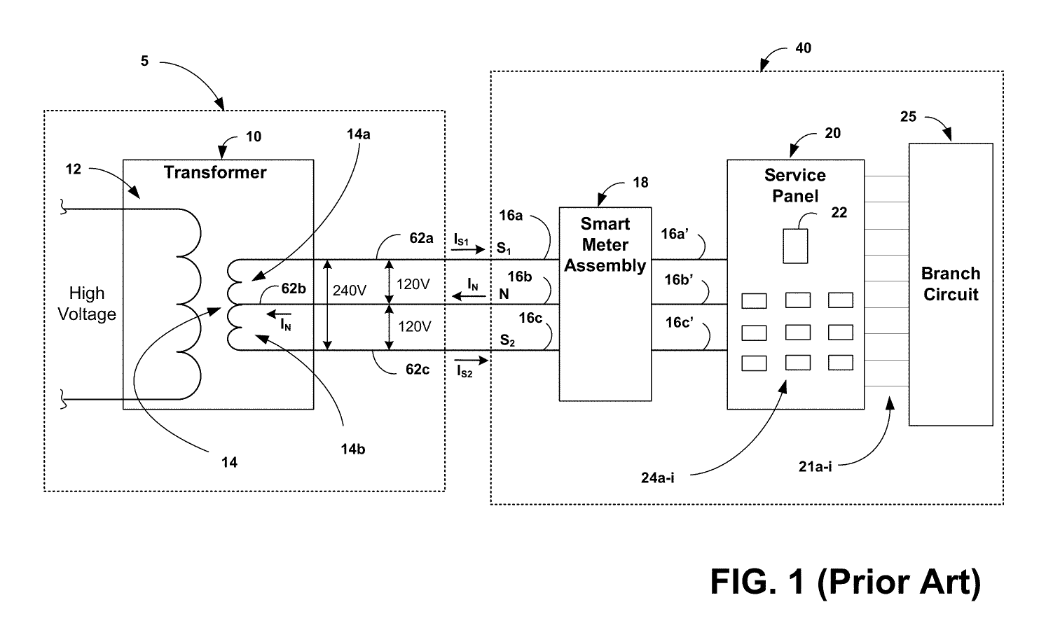

FIG. 1 illustrates a typical single-phase, three-line residential electrical power service 5 deployed in the United States. Those of skill in the art will appreciate that this form of service is being used as an example only, and that the embodiments of the invention disclosed herein are not intended to be limited thereto. Those of skill in the art will appreciate that application of the embodiments of the invention can be extended by example to any type of electrical service.

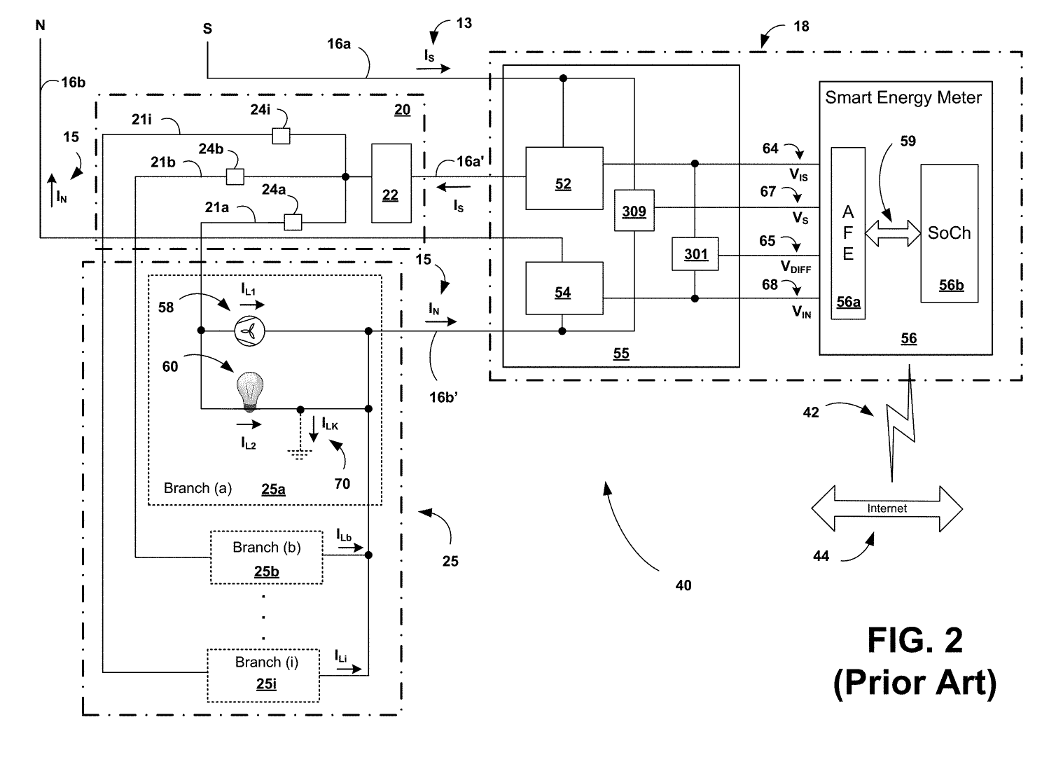

Transformer 10 of service 5 steps the voltage down using a primary coil 12 to secondary coil 14 to produce a single-phase supply of 240 volts across secondary coil 14 and lines 62a and 62c. Coil 14 is then split into halves 14a and 14b using a coil tap in the form of neutral wire 62b, so that the single phase 240-volt supply is divided into two split-phases S₁ and S₂, of 120 volts each. These voltages are provided to the electronic distribution system 40 for a premises (e.g. a residence) between service lines S₁ 16a/N 16b and between service lines S₂ 16c/N 16b. Those of skill in the art will appreciate that this service configuration permits a resident of the premises to run smaller appliances and resistive loads (such as resistive lighting element 60 and appliance fan 58 of FIG. 2) using one of the 120-volt (split-phase) service lines S₁ 16a or S₂ 16c in conjunction with neutral service line N 16b, and to run load devices such as air conditioners at the full 240 volts provided between service lines S₁ 16a and S₂ 16c.

As previously discussed, the service lines S₁, N, S₂ (16a-c respectively) can be coupled to the electrical distribution system 40 of a residence or commercial building for example, that can include an electronic (“smart”) meter assembly 18 (in lieu of a prior art watt-hour meter based on an electromechanical design). Smart meter assembly 18 electronically meters the power drawn by a consumer during some fixed billing period. Meter assembly 18 includes an electronic (“smart”) meter (56, FIG. 2) that measures the current directly from service lines 16a (S₁), 16c (S₂) and neutral N 16b. Those of skill in the art will appreciate that most residential and small business consumers will typically use only one of the two wires S₁ 16a′, S₂ 16c′ to run one half of the single phase voltage (120 volts as illustrated) to the service panel 20 of FIG. 1. Thus, for purposes of simplicity, the following discussion will represent the split-phase service wires as S 16a and N 16b.

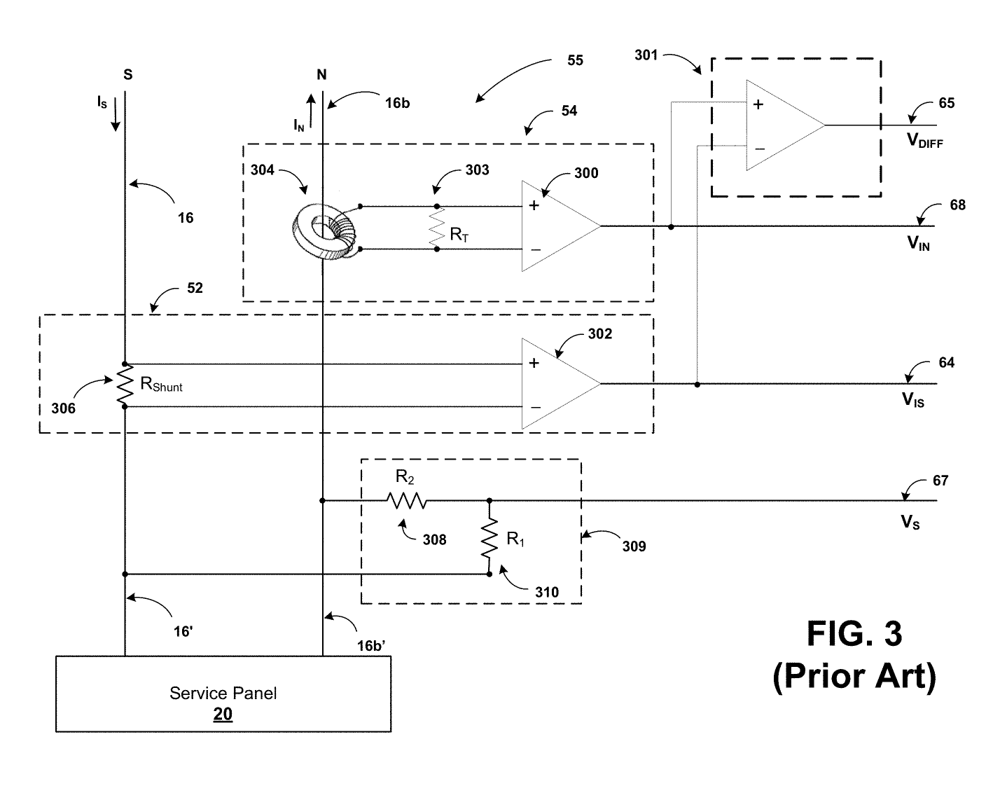

FIG. 2 illustrates a simple block diagram representation of the prior art electrical distribution system 40, electrically coupled to the Single Phase Two Wire service 5 of FIG. 1 through service lines S 16a and N 16b. Electrical distribution system 40 includes an assembly of sensors 55 that provides output voltages as signals that are utilized by the smart energy meter 56. Sensor assembly 55 includes a current sensor 52, coupled to line S 16a to sense the current being drawn through line S 16a from the service by the branch circuit 25. The current is passed through sensor 52 to the service panel to the branch circuit 25 through line 16a′. Current sensor 52 will be presented in more detail below with reference to FIG. 3.

Sensor 52 continually senses the drawn current I_{S} 13 and typically provides an output voltage V_{IS} 64 to the smart meter 56, the value of which is proportional to the sensed current at any given time. Sensor assembly 55 further provides an output V_{S} 67 that is proportional to the line voltage V_{S} 67 via voltage divider 309, which continuously represents the voltage being presented by the service across the branch circuit by the service between service lines S 16a and N 16b. Voltage divider 309 will be presented in more detail below with reference to FIG. 3. From these two signals V_{IS} 64 and V_{S} 67, smart meter 56 can calculate continuously the power being consumed by the branch circuit 25 over some predetermined interval of time for billing purposes.

The current I_{S} flows through sensor 52 into the panel 20 via S 16a′ through main circuit breaker 22, through individual breakers 24a-i and into the respective branches 25a-i though lines 21a-i respectively. Only a few of the branches 25 are shown for brevity. Each branch of the branch circuit 25 typically distributes one of the split-phase lines S 16a′ to various load devices (e.g. lights, fans appliances, etc.) coupled to the electrical branch circuit 25. The circuit breaker 24(a-i) for each branch can be actuated manually and can be tripped opened automatically when the load current drawn by devices coupled to the branch exceeds a predetermined threshold indicating the presence of a short-circuit. As previously discussed, main breaker 22 can be automatically or manually actuated to disconnect the service line S₁ 16a′ from the entire electrical branch circuit 25.

Branch 25a is a simplified example to show two load devices fan 58 and light fixture 60 coupled thereto. Fan 58 draws load current I_{L1} and light fixture 60 draws load current I_{L2}, which are then recombined with currents drawn by the other branches 25 (i.e. I_{Lb}-I_{Li}) and returned as I_{N} 15 through line service line 16b′ to the smart meter assembly. I_{LK} 70 is a potential leakage path to ground, otherwise known as a ground fault. When no leakage current is present in the branch circuit 25, return load current I_{N} 15 flowing through the neutral service lines N 16b′, 16b will be virtually equal to service load current I_{S} 13. When leakage current is present, I_{LK} 70 will be subtracted from the total return current I_{N} 15. Potential parallel arc fault current I_{PA} 73 and series arc fault current I_{SA} 71 are shown flowing in branch 25a of electrical branch circuit 25 as well. The fault current I_{PA} 73 will not contribute in any significant way to leakage current I_{LK} 70.

Returned service load current I_{N} 15 can be sensed by a second current sensor 54 that can be deployed to directly sense the magnitude of the AC current I_{N} 15 flowing in the split-phase service line N 16b. Prior art current sensor 54 senses the magnitude of the return AC current I_{N} 15 flowing in the neutral service line N 16b and provides an output V_{IN} 68 to Smart Meter 56 representing the magnitude of the return current I_{N} 15. Current sensor 54 is also presented in more detail below with reference to FIG. 3. Differential current sensor 301 of sensor assembly 55 can be used to detect the difference between the outputs of the two sensors 52, 54 using, for example, as a differential amplifier, the difference being a voltage output V_{DIFF} 65 that is proportional to any leakage current I_{LK} 70.

The voltage outputs V_{IS} 64, V_{IN} 68, V_{DIFF} 65 and V_{S} 67 from the current sensor assembly 55 are provided as inputs to an analog front end (AFE) 56a of processing device 56. AFE 56a typically includes an Analog to Digital (A/D converter) that digitizes samples of the voltages of outputs V_{IS} 64 and V_{IN} 68 and are converted to the current values they represent as the currents are directly sensed by sensors 52 and/or 54 respectively. Output V_{S} 67 is sampled and converted to digital values of the line voltage. The smart meter processing device 56 also includes digital circuitry in the form of SoCh (system on a chip) 56b, including a microprocessor and associated software, that calculates the power consumption using the digitized samples of the sensed current I_{S} 13 to establish the RMS value of the current I_{S} 13. These RMS values are multiplied by the voltage sampled at V_{S} 67, along with the calculated power factor and aggregated over time to establish the power consumed over a period of time such as a month for billing purposes. The presence of values of V_{DIFF} 65 that exceed some predetermined threshold can be used to turn on a warning light to indicate the presence of leakage current in branch circuit 25.

Those of skill in the art will appreciate that the smart meter processing device 56 can be one of a number of commercially available proprietary designs. One such device is the MCF51EM256 microcontroller manufactured by Freescale Semiconductor. Another is the MAX71020 single chip meter made by Silergy Corporation. These exemplary devices, or variants thereof, can be used as device 56b of smart meter 56. Typically, they are designed to be compatible with a proprietary requisite analog front-end (AFE) 56a as part of the overall design and communicate with one another through an interface 59.

SoCh 56b is the digital signal processing portion of the smart meter that typically includes a microprocessor of some kind and non-transitory memory for storing software executed by the microprocessor. Processing portion 56b, in addition to calculating energy consumption by the electrical distribution system 40, can perform various additional processing functions using the digitized data. For example, it can be programmed to compensate for various environmental conditions such as temperature and altitude and providing network communication function by which the calculated information can be logged and transmitted to the power supplier for analysis and billing. It can also be programmed to monitor parameters that reflect the well-being of the electrical distribution system 40, including the appliances and other load devices coupled thereto. It can be programmed to analyze the load current for indications of the presence of faults that can lead to fire or hazardous conditions such as faults.

SoCh 56b will also typically include the ability to connect to the Internet 44 over some network connection 42 which can be hard wired or wireless. This will enable the metering information as well as functional status and well-being information to be transmitted back both to the service provider as well as the user. Those of skill in the art will appreciate that the fine details of the smart meter designs are well-documented and are outside the scope of this disclosure, which is directed to improvements in the sensor assembly employed to provide the input signals required by such smart meter chip sets.

Interface 59 facilitates transfer of the digitized form of the input signals, generated by the AFE 56a, to the SoCh digital processing circuitry 56b. Those of skill in the art will appreciate that this interface can be complex, not only to provide signals that can be processed by the SoCh circuitry, but also to provide galvanic isolation between the two circuits given that they will typically be operating at disparate voltages. This is especially true if the current sensor 52 is operating at the line voltage of 120 volts in the example of FIG. 1.

As illustrated in FIG. 3, prior art current sensor 52 of the sensor assembly 55 is typically implemented as a precision shunt (series) resistor R_{SHUNT} 306, which is placed in series with the split-phase service line S 16a. The voltage across R_{SHUNT} 306 is deliberately kept small to minimize the voltage loss in the S 16a service line, as well as to minimize power dissipation by R_{SHUNT} 306. An amplifier 302 (and other associated circuitry) is therefore typically used to amplify the small output voltage drop across R_{SHUNT} 306 to provide V_{IS} 64 as a viable signal to proportionally represent the magnitude of current I_{S} 13.

While it is not generally required by code that the current flowing in the neutral path N 16b be measured, it can be useful to do so if one wishes to detect the presence of leakage current in the branch circuit 25 of the premises. Those of skill in the art will appreciate that the relatively less expensive shunt or series resistor 306 of sensor 52 is not permitted to be used for sensing current in the neutral wire N 16b. The neutral service wire N 16b, in accordance with the National Electrical Code (NEC), is not permitted to be broken or interrupted with components in series therewith. The neutral service wire is required to be bonded to ground at the head of the service. Interrupting N 16b with a component such as R_{SHUNT} 306 creates a voltage drop between neutral and ground and poses the possibility that a failing component can cause N 16b to rise to a voltage level near that of service line S 16a (e.g. 120 volts) within the premises to which the service is being provided. This is an impermissible hazard.

Current sensor 54 is therefore one that must provide galvanic isolation, such as one magnetically coupled to the neutral service line 16b, 16b′ as a toroid current transformer. Sensor 54 employs a core 304 through which line N 16b, 16b′ passes. This permits current flowing in neutral line N 16b, 16b′ to be sensed without physically interrupting it. The secondary windings of the transformer are coupled to burden resistor R_{T} 303. The voltage across R_{T} 303 is amplified by amplifier 300 to create an output V_{IN} 68, which proportionally represents the current I_{N} 15 flowing through the neutral conductor 16b. V_{IN} 68 is derived from the voltage drop across R_{T} 303 and the turns ratio of the toroid transformer 54. As previously discussed, the potentially large currents drawn by a large load premises will require a large and very costly transformer for that purpose, which discourages sensing the neutral current to identify leakage current at the service current level.

As illustrated in FIG. 2, the presence of a ground fault can lead to the flow of leakage current I_{LK} 70 flowing to ground in one or more of the branches. This leakage current will be reflected as an imbalance between the current flowing in neutral line N 16b, 16b′ and the current flowing in the service lines that is roughly equal to the magnitude of the leakage current I_{LK} 70. As illustrated in FIG. 2 and FIG. 3, a comparison of the current sensed by sensor 52 and the current sensed by sensor 54 can be accomplished through a circuit such as a differential op-amp 300 or other suitable comparative technique, which determines the difference and amplifies it to produce voltage output V_{DIFF} 65. This difference in current magnitude is input into the AFE 56a of smart meter 56 and if the difference represented by I_{LK} 70 reaches and/or surpasses some predetermined threshold, the presence of a ground fault can be inferred therefrom.

It should be noted that while it has been suggested in the prior art that it might be desirable to sense the return load current in the neutral service line when using smart meters, it is unclear if this is ever implemented in practice because of the additional expense to provide the necessarily large and expensive toroid transformer as a current sensor to measure the high magnitude of current in the neutral line. It also adds complexity to provide the requisite circuitry to detect and amplify the difference between outputs of two different types of sensors. While there are benefits to testing for leakage current at the service metering level, it may be the prevailing belief in the art that the expense for such testing can be avoided because devices already exist to detect leakage at the branch level and any additional benefit may not be warranted in view of the additional cost.

This is also why detection of arc faults at their incipiency by monitoring the service current at the metering level is not currently performed. A shunt resistor is necessarily very small to minimize power dissipation, but this produces a very small voltage signal for used in sensing the service current. As a result, the signal to noise ratio will likely be less than ideal for the detection of the high frequency components of the service current affected by arc currents. In addition, the signal must be amplified for use by the smart meter, which can be only further to the detriment of the shunt resistor 52 being a less than desirable source of information for detecting the manifestations of arc current on the service current.

Because the sensor 52 is most typically a shunt resistor 306 in prior art sensor assemblies 55, sensor 52 operates at the full service line voltage S 16b. This will require that interface 59 provide galvanic isolation between the AFE 56a and the SoCh 56b because they are processing signals at two disparate voltage levels. Such isolation schemes can include opto-isolation and pulse transformer circuits, which are currently employed in the AFEs of existing smart meter chips designed to interface with shunt resistors.

Thus, the optimal type of current sensor that produces the requisite bandwidth for detecting the effects of series and parallel arc currents is a current transformer. But a current transformer that can detect the magnitudes of service current that are drawn from an electric service while maintaining the requisite bandwidth are very large and very expensive as discussed above. This is why such a test is presently only performed by a technician, who provides the large and expensive current transformer that can be clamped around the service line to test for the presence of arc currents. It will be appreciated that such a test will only provide information for present condition of the insulation for the wiring but provides no information any point of time in the future. This also explains why devices called Arc Fault Circuit Interrupter's (AFCIs) presently being used for detecting series arc faults at the branch level are expensive. Even though they only have to sense the portion of the service current detection of service current flowing in a single branch. They also employ current transformers, albeit only the fraction thereof that flows in the particular branch it is protecting.

As previously discussed, AFCI devices could be used in branch circuit 25b, but they are expensive, and they are designed to trip open the branch circuit at a point that there is some level of actual danger present. They do not have the luxury of detecting what may be the very first instance of an arc current signature on the current signal, and to continue to gather data to confirm that is in fact an arc fault that is still below the magnitude at which a fire may start. Even at the significantly higher thresholds they currently employ, they are still known for nuisance tripping on high frequency spikes that can be caused by switches and noisy appliances, which is quite inconvenient if not costly. Integrating the intelligence to truly discriminate these types of arc fault currents at the service current level would be able to leverage the ability of the smart meter to perform the signal processing and data analysis required to provide early detection of these faults in every premises. Moreover, the cost of development of such processing can be amortized over the hundreds of millions of customers that would be benefitting from the ability to prevent the fires associated with such faults.

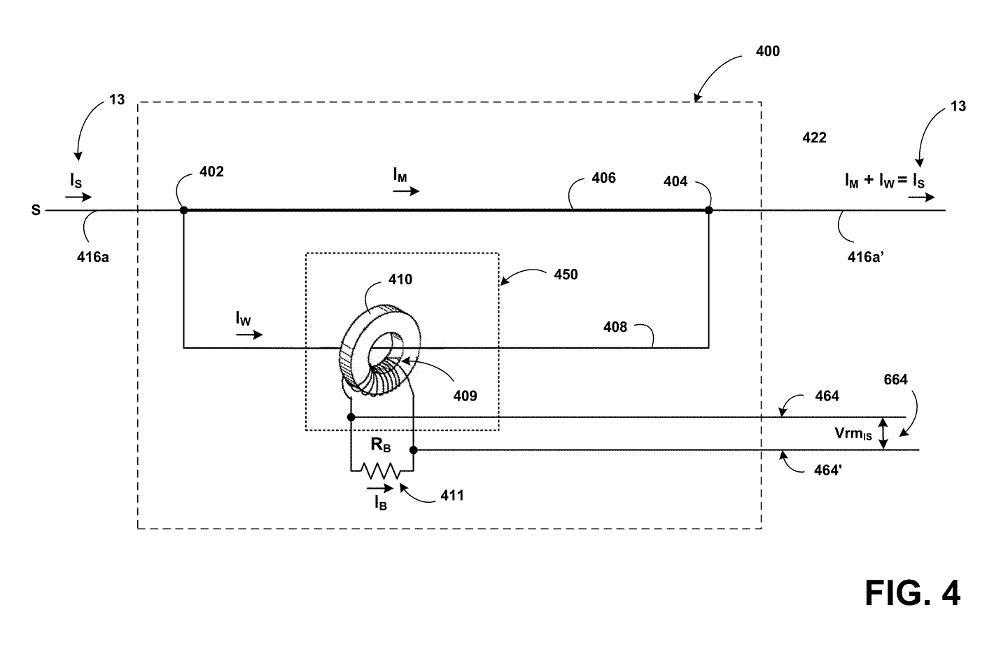

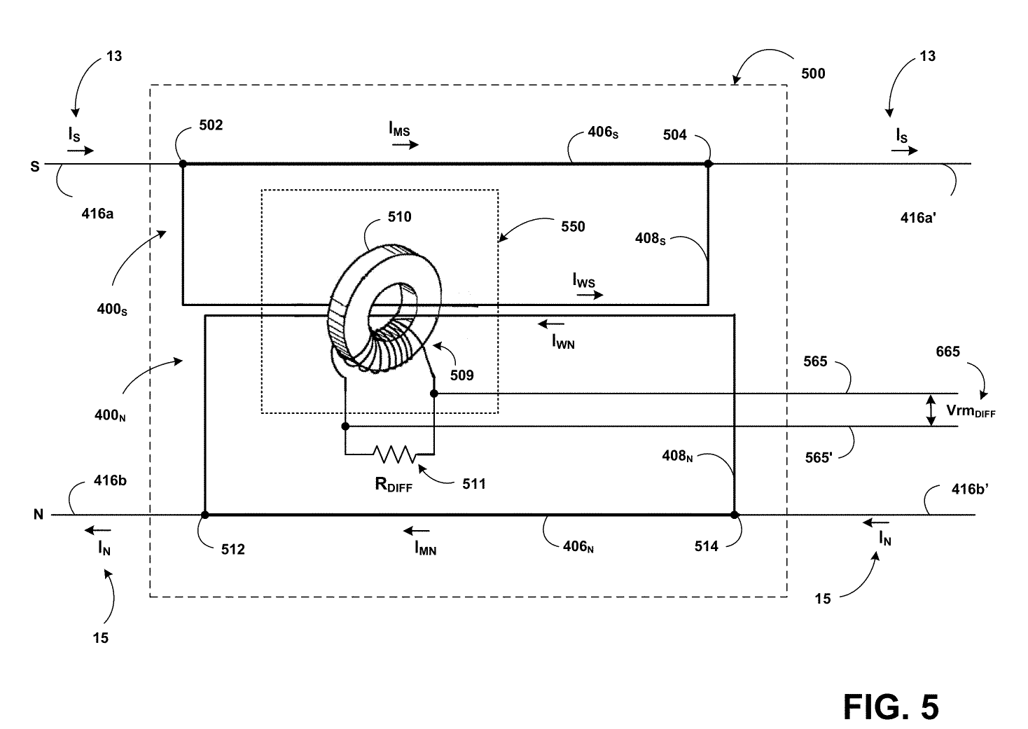

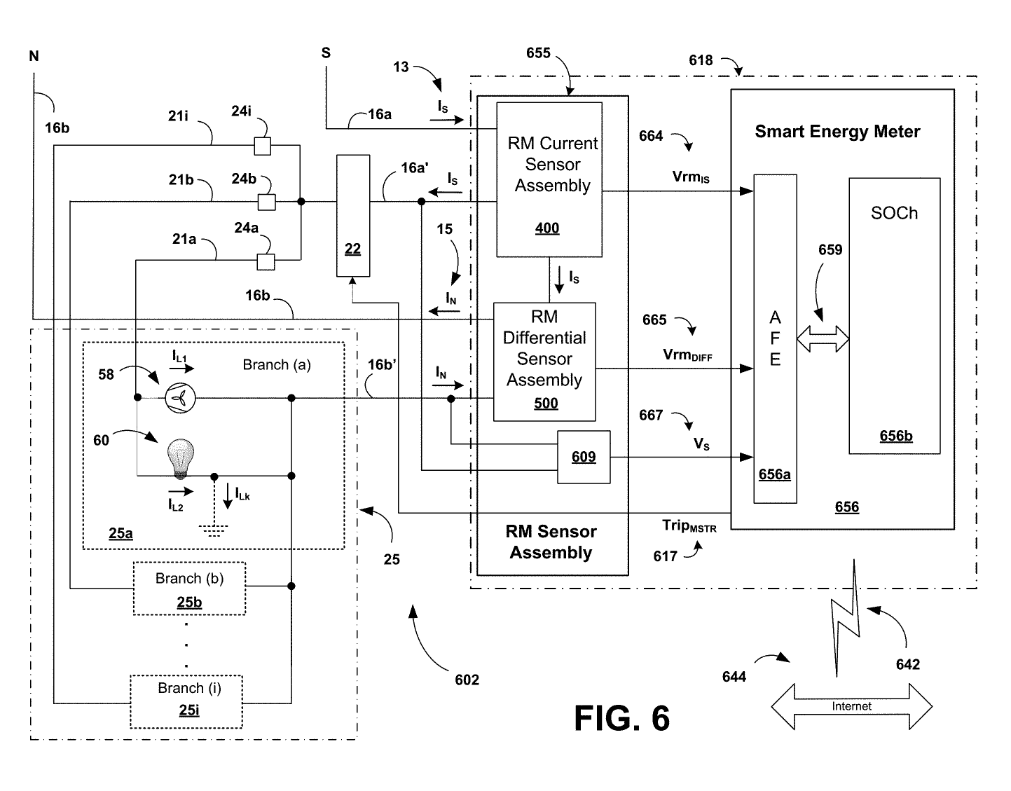

FIG. 6 illustrates an RM sensor assembly 655 that replaces the prior art current sensor assembly 55 of FIGS. 2 and 3. Ratio metric current sensor assembly 400 replaces sensor 52, which is typically a shunt resistor and associated amplification circuit 302 as previously described (FIG. 3), and RM differential current sensor assembly 500 replaces large current transformer sensor 55 and differential amplifier 301, (FIG. 2). RM current assemblies 400 and 500 will be discussed in more detail below with reference to FIGS. 4 and 5 respectively below. Voltage divider 609 is largely the same as that of the prior art (309, FIG. 3). Both RM sensor assemblies 400 and 500 of RM sensor assembly 655 leverage current dividers that can be configured and manufactured using PC board technology to indirectly sense the service current I_{S} 13 that enables the use of small toroidal transformers 450, 550 respectively. The toroidal transformers 450, 550 are inexpensive, simple to mount on PC boards and provide the requisite galvanic isolation that shunt resistor 52 does not. Reducing the current actually sensed to a fraction of the full service current I_{S} 13 drawn by a premises enables the toroidal transformer 450, 550 to be reduced substantially in both size and cost from the current transformer that otherwise would have to be used to accurately sense the service current directly from the service lines while maintaining bandwidth (the reason prior art sensor 54 is not used), and eliminates the disadvantages of using a shunt resistor as previously discussed.

FIG. 4 illustrates an embodiment of a ratio metric (RM) current sensor assembly 400 of the invention that can directly replace the prior art sensor 52 of the smart meter sensor assembly 55 of FIGS. 2 and 3. Sensor assembly 400 can be configured to provide a significantly smaller, less costly and more accurate current measurement device to support tariff metering of electric power using smart meters compared to sensors heretofore employed in the prior art such applications as described above. In addition, bandwidth is preserved when sensing these high magnitude currents, which supports accurate wellness monitoring of the electrical distribution system (600, FIG. 6) and more particularly, the branch circuit (25, FIG. 6). With respect to the return current I_{N} 15, it should be noted that most applications do not typically require that smart meter (656, FIG. 6) receive a direct measurement output V_{IN} 68 for the value of the return current. The sensed return current is typically only used in conjunction with a differential amplifier to provide an indication of leakage current as previously discussed. Notwithstanding, an RM current sensor assembly 400 of the invention would be sufficiently cost-effective to provide such a sensed current output to a smart meter assembly (656, FIG. 6) if one if is desired.

As shown in FIG. 4, a low impedance conductor 116a to 116a′ is provided as a wire or PC board trace that can be placed in series with (and has substantially the same conductivity as) the service line S 16a in lieu of the shunt resistor 52 of the prior art. A second conductor 408 of relatively higher impedance compared to the phase line S 16a and conductor 116a to 116a′, is provided as a flexible wire or PC board trace that is fed through a core 410 to form a primary of the toroid inductor of a toroidal current transformer 450.

Conductor 408 is further conductively coupled to conductor 116a to 116a′ at points 402 and 404 respectively. This establishes a current divider having a main path 406 that incorporates conductor 116a to 116a′ and a secondary high-impedance path formed by conductor 408. Based on the relative impedances of the two paths, the AC current I_{W} flowing in the secondary path of the current divider formed by the wire 408 can be made proportionally much smaller in magnitude than the current I_{M} flowing in the main path 406 formed by the portion of low impedance conductor 116a to 116a′ between points 402 and 404.

Those of skill in the art will appreciate that this same current divider can be configured by conductively coupling the high-impedance conductor 408 directly to the service line 16a to 16a′ if practicable. Those of skill in the art will appreciate that the first calibration as discussed below would have to be conducted in circuit for each installation rather than as part of the process of manufacturing a standardized device.

A burden resistor R_{B} 411 having a predetermined resistance value is coupled across the secondary 409 of toroidal current transformer 450. The current I_{B} flowing through burden resistor R_{B} 411 is equal to: the voltage drop across R_{B} 411 (between lines 464, 464′), divided by the value of R_{B} and is the sensed current output Vrm_{IS} 664 of the RM current sensor assembly 400. The current I_{W} flowing through the wire 408 is equal to I_{B} divided by the turns ratio of toroid 450. The magnitude of the current I_{S} 13, which is drawn from the service by the branch circuit of the premises and flows through phase line S 16a and conductor 116a to 116a′ can be derived by multiplying I_{W} by the complex current ratio between I_{M} and I_{B} to ascertain I_{M}, and then adding I_{M} and I_{B} to get I_{S} 13.

The conductor forming secondary path 408 can be a flexible wire to ensure its easy threading through the core 410, and to maintain sufficient distance from the main path conductor 406, thereby eliminating electro-magnetic interference that is common to monolithic prior art implementations of current divider based current sensors. Any wire used for secondary path 408 is preferably insulated, which will prevent short-circuits between the wire 408 and other proximate conductive paths. The core 410 is preferably conformally coated and can be directly mounted to a printed circuit board (PCB). Those of skill in the art will recognize that if the wire 408 and the main path 406 are implemented as traces on a PCB, they can also be separated and insulated from one another by, for example, locating each on a different interconnect level on the PCB. In either case, it will be appreciated that it will not be difficult to avoid electromagnetic interference by ensuring that there is sufficient distance between the wire forming the secondary path 408 of the current divider and the main path formed by the conductor 116a, 116a′ between the points 402 and 404.

Those of skill in the art will appreciate that there are a number considerations that affect the accuracy of the RM current sensor assembly 400 in sensing service current for metering purposes. First, the classes of service current can range from 60 amps at the lower end of residential service to 800 amps for industrial three-phase service. The typical target for accuracy in current metering applications is 1% but should be as accurate as practicable. It is highly unlikely that such an accuracy is being achieved over the entire range of such large magnitude current ranges with smart metering products as limited by prior art current sensor technology. The RM current sensor assembly 400 can be manufactured and implemented to achieve this level of accuracy in view of the following description of a method of manufacturing.

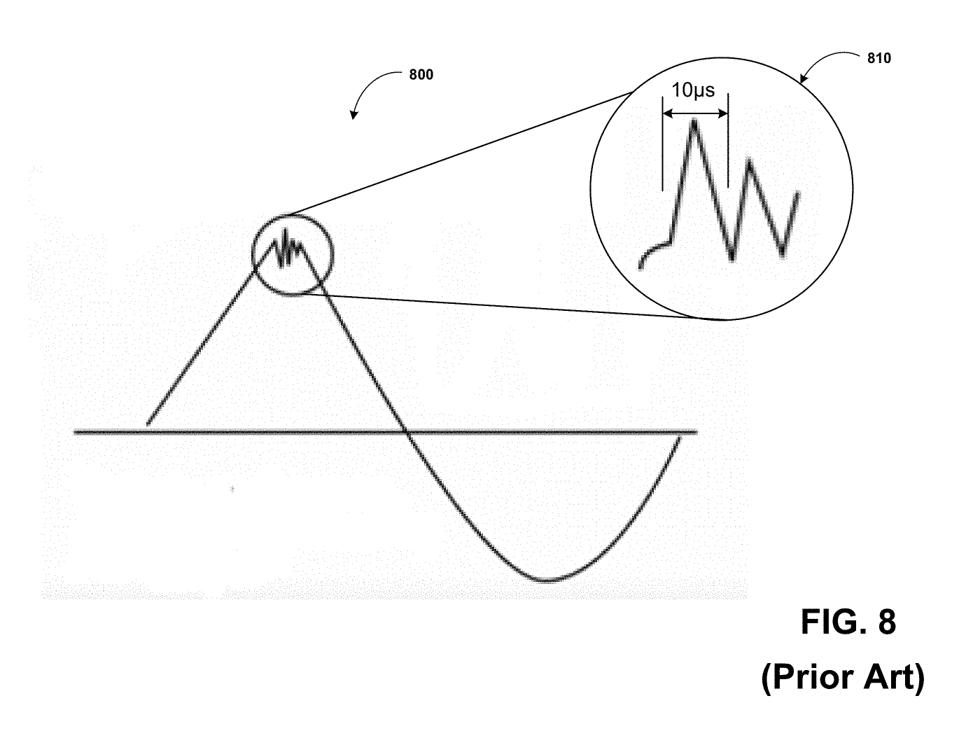

Those of skill in the art will appreciate that ideally, the overall proportionality of the RM current sensor assembly 400, between the service current as its input and the sensed current output Vrm_{IS} 664 across the burden resistor R_{B} 411, would be constant across the whole range (i.e. would be linearly proportional). Those of skill in the art will recognize that a toroidal current transformer has a B-H curve as shown generally in FIG. 8A and an average B-H curve as generally illustrated in FIG. 8B. While the curve is substantially linear up to a certain magnitude of current for a given core and number of turns, eventually the core saturates and the response to further increases in the magnitude of the service current becomes increasingly non-linear.

Those of skill in the art will recognize that a toroidal current transformer that could operate at a substantially linear response over a range of high magnitude current such as may be drawn from a 200 amp electrical service would be very large and costly. The current divider of the current sensor assembly 400 can be used provide a substantial rationing of the currents such that the size of the core can be significantly reduced while still operating within the substantially linear portion its B-H curve. However, prior art attempts to incorporate a current divider with a toroidal current sensor device have largely failed to produce practicable embodiments. This is because they have been manufactured under the initial premise that one must first manufacture the current divider to a high degree of accuracy. This led to expensive, bulky, monolithic, devices that are hard to manufacture and have high frequency issues caused by magnetic cross-coupling between the conductive paths of the current divider.

The RM current sensor assembly 400 is instead manufactured from the premise that one can establish a target proportionality (which includes manufacturing the current divider to approximate a desired current ratio) of the current sensor assembly 400, and then calibrating out the inaccuracy in the parameters that affect the physically realized or actual proportionality to achieve the required degree of accuracy through simple adjustment of the of burden resistor R_{B} 411 value as part of the manufacturing process. This permits the current sensor assembly to be manufactured using less expensive printed circuit board techniques through calibration.

Thus, for a given range of service current, a target proportionality can be formulated for a toroidal transformer of a given size and core material that can be optimized for size and cost. This permits the current transformer to operate over a predetermined range of service current while remaining substantially within the more linear portion of its operation. For example, one can start with a desired core size and material for the current transformer that optimizes the size and cost of manufacture, and to provide a desired dynamic range of output voltage for Vrm_{IS} 664 based on its operational curve. Based on the maximum current of the current range of the service provided by service line S 16a, one can specify a desirable current divider ratio and turns ratio that will produce the desired output voltage range for Vrm_{IS} 664 while maintaining the current transformer within its substantially linear range of operation. This desired output range can be, for example, about 0.2-5 volts. To achieve a range of 0.2 to 5 volts for Vrm_{IS} 664 over the current range of a 200 amp service, the current I_{W} flowing in the secondary path could have a desirable range of about 50 milliamps at the top of the range, down to about 2 milliamps at the lower range based on the configuration of the current transformer. If a current transformer is implemented with a single turn in the secondary so that it produces the same current that flows through the secondary path of the current divider, and the value of R_{B} 411 is initially predetermined to be 100 ohms, the current ratio required would be about 4000 to 1 and the voltage signal across R_{B} 411 would be 0.05×100=5 Volts at the top of the output range. Thus, conductors forming the two paths can be specified based on, for example, their estimated resistance values to produce such a ratio.

Those of skill in the art will appreciate that one could perform this configuring of the current sensor assembly to achieve a target proportionality for a current transformer that is optimally sized for cost and linear operation, by building a physical circuit and physically manipulating circuit components to arrive at a combination of circuit parameters that achieves the target proportionality. However, it may be more expedient to first employ one of the myriad of commercially available circuit design software tools that permits one to simulate the circuit using software by which to arrive at a desired configuration that achieves the targeted proportionality. This includes specifying the geometric proportions of the conductive paths by which to achieve the desired current/impedance ratio of the current divider. The configuration can be verified to approximate the target proportionality without iteratively manufacturing, adjusting and re-testing.

Notwithstanding, at some point the current sensor assembly 400 is then physically configured (i.e. assembled/manufactured) as part of the configuration process. Manufacturing the physical circuit produces a current sensor assembly with an actual proportionality that can be tested to see if it produces the requisite accuracy. This is because the simulated or calculated configuration is based on a theoretical configuration including estimates of the current divider impedance ratio and the proportionality of the current transformer 450. If the actual proportionality realized by manufacturing the current sensor assembly fails to achieve the requisite accuracy, various forms of calibration described below can be used to bring the current sensor assembly within the predetermined degree of accuracy specified for the application.

It will be appreciated that if the service current information is derived from the current sensor assembly 400, which is also providing the smart meter with sensed current information for purposes of metering energy consumption based on the magnitude of the service current, it will be derived from a current sensor assembly that has been calibrated to produce an accuracy required for that function. Thus, if well-known time domain techniques are used to detect, for example, series arc faults, the requisite accuracy of the service current information is provided. See related US Patent Application No. titled “A REDUCED COST RATIO METRIC MEASUREMENT TECHNIQUE FOR TARIFF METERING AND ELECTRICAL BRANCH CIRCUIT PROTECTION” for the details regarding such calibration.

However, for performing signature analysis or arc fault detection on the sensed current output in the frequency domain, it is not necessary to know the proportionality of the RM current sensor assembly with any requisite accuracy. The magnitudes of the frequency components of interest that are being analyzed can be made relative to the fundamental and thus the overall magnitude it not critical to such analysis. Thus, an uncalibrated version of RM current sensor assembly 400 could be used to provide a separate source of the sensed current information that can be used for frequency spectrum analysis of the service current if desired. It will be appreciated that the RM current sensor assembly 400 significantly improves the bandwidth performance in preserving the high-frequency content of the sensed service current for facilitating such analysis, and at a cost and size that has been significantly reduced from current sensors presently used.

As previously discussed, the current I_{N} flowing in the neutral service wire (N 16b, FIGS. 1 and 2A-B) can also be sensed for purposes of determining whether ground faults exist that will lead to an imbalance between I_{S} and I_{N} resulting from the presence of a leakage current to ground such as I_{LK} 70. As previously discussed, the prior art suggests that monitoring for leakage current will require a large and therefore costly current transformer to sense current in the neutral service line, and an additional means to compare the current outputs and to amplify that sensed difference. Those of skill in the art will appreciate that the RM current measurement technique of the invention could be accomplished in a similar manner by using an RM current sensor assembly 400 for each service line and a differential amplifier to detect imbalances in the two currents. However, the RM approach can be further leveraged as described below to easily configure an RM differential current sensor assembly 500 of the invention that requires a single toroid to render the detection of leakage current at the metering level far more cost-effective. Moreover, this device can be used in place of prior art components currently deployed at the individual branch level.

In an embodiment of the invention as illustrated in FIG. 5, the RM current measuring technique can be leveraged to produce a small and integrated RM differential current sensor assembly 500. The RM current measurement technique of the invention enables the easy integration of two of the RM current sensor assemblies 400 into a differential current sensor assembly 500 of the invention that shares the same core as illustrated in FIG. 5. Thus, the differential current sensor of FIG. 5 can replace prior art current sensor 52 (including R_{SHUNT} 306 and operational amplifier 300), current transformer 54 (including toroid 304, burden resistor 303 and op amp 300) and differential amplifier 301.

The RM differential sensor assembly 500 of the invention in effect integrates or merges two RM current sensor assemblies (400_{S}, 400_{N} of FIG. 5) back to back (400, FIG. 4), which measure the current flowing in the S 16a and N 16b service lines respectively. The RM sensor assemblies 400_{S} and 400_{N} are integrated in that they share a single toroid 550, including core 510 and burden resistor R_{DIFF} 511. This physical integration is facilitated by the fact that the high-impedance conductors used to form secondary paths 408_{S}, 408_{N} of sensors assemblies 400_{S} and 400_{N} respectively are, for example: thin, flexible, insulated wires, or printed circuit board (PCB) traces (insulated from one another by occupying different interconnect levels of the PCB), that can be easily fed or routed (respectively) through the shared core 510 of toroid 550. While the high-impedance conductors forming secondary paths 408_{S}, 408_{N} could be attached directly to existing service lines S 16a and N 16b, those of skill in the art will appreciate that it is more practicable to manufacture RM differential sensor assembly 500 to be placed in series with the service lines through low impedance conductors 416a to 416a′ and 416b to 416′ to facilitate integration of the current sensing function into a smart meter assembly 618, FIG. 6 as a current sensor assembly 400, FIG. 6.

The current flowing in the I_{S} service line S 16a is divided into currents I_{MS} (flowing in the main path 406_{S} of the current divider of RM current sensor assembly 400_{S}) and I_{WS} (flowing in the secondary path 408_{S} of the RM sensor assembly 400_{S}). Likewise, the current I_{N} flowing in the neutral service line N 16b is divided into currents I_{MN} (flowing in the main path 406_{N} of the current divider of RM current sensor assembly 400_{N}) and I_{WS} (flowing in the secondary path 408_{N} of the RM sensor assembly 400_{N}). As previously discussed, I_{S} should be equal to I_{N} in the absence of any leakage current. Thus, so long as the current ratios of the current dividers of 400_{S} and 400_{N} are approximately equal (any difference can be calibrated out), I_{WS} and I_{WN} will be equal. In this case, there will be virtually zero differential current and Vrm_{DIFF} 665 will be zero volts. As the presence of leakage current (I_{LK} 70, FIG. 6A) increases in an electrical branch circuit 25, the differential output voltage Vrm_{DIFF} 665 increases proportionally to the increasing differential between the currents I_{S} and I_{N}.

For the single phase residential application, these conductors forming the secondary paths are arranged so that their respective currents I_{WS} and I_{WN} are fed or passed through the same core 510 in an anti-phase relationship with one another such that any difference or imbalance in the current flowing in those secondary paths will produce a magnetic flux that will generate a voltage Vrm_{DIFF} 665 across burden resistor R_{DIFF} 511 between output lines 565, 565′ that is proportional to the difference in currents. Those of skill in the art will appreciate that the symmetry of the RM differential amplifier renders Vrm_{DIFF} 665 more accurately than prior art solutions, as any non-linearity or other errors between the two sensed currents will tend to cancel each other out. Using a single core and a common (RM) method of current measurement inherently eliminates non-linearity and other variables common in prior art methodologies, including those resulting from the use of two different types of current sensor to measure the currents in S₁ 16 and N 16b as illustrated in FIGS. 2 and 3.

The parameters of the RM differential current sensor assembly 500 can be designed and calibrated in the same manner as described above for RM current sensor assembly 400. However, the RM differential sensor assembly should require no calibration provided that manufacturing tolerances are within the predetermined degree of accuracy required for detection of leakage currents. The accuracy for leakage current should be more relaxed than that required to meter power consumption. Thus, a tooled initial calibration to establish the same proportionality for each current may all that is required. Any remaining imbalance exists as an initial condition can be simply normalized when establishing any protection thresholds. It will be appreciated that even if the impedance ratios are not calibrated to produce identical proportionalities between the two common current dividers, any amount of initial imbalance can be normalized in creating protection threshold(s) established for indicating the presence of leakage current.

Those of skill in the art will appreciate that a plurality of threshold values of V_{DIFF} can be established by which to trigger increasingly more urgent actions related to the presence of leakage current that exceeds some tolerable level established by the threshold value of Vrm_{DIFF} 665. This can now be done at the service level by the smart meter 656 itself and can thus monitor for an overall cumulative leakage for the entire branch circuit 25. Multiple thresholds can be established, wherein reaching or exceeding a first threshold level can result in a warning indicator (e.g. a light, a sound, etc.), and messages can be sent to the user and the provider via the Internet 644 over network connection 642. Exceeding a highest threshold value could lead to an actual opening of the main breaker 22 of the branch circuit 25 electronically using a control signal (Trip_{MSTR}617) generated in response thereto.

The RM sensor assembly 655 is therefore intended to be virtually drop-in replaceable for the prior art current sensor assembly 55, FIG. 2. Similar to the path shown in FIG. 2, the split-phase service line S 16a is provided as an input to smart meter assembly 618, which is passed through both RM Current Sensor assembly 400 and RM differential current sensor assembly 500, before emerging as S 16a′ to be coupled to the master circuit breaker 22 of service panel 20, FIG. 1. Neutral service line N 16b, 16b′ is likewise provided as a passthrough input and output through RM differential current sensor 500 as illustrated in FIG. 6. Thus, all of the prior art sensors of prior art sensor assembly 55, including all of the associated circuitry by which to amplify sensed current signals and to detect and amplify the difference between I_{S} 13 and I_{N} 15, can be replaced with one small and inexpensively manufactured RM current sensor assembly 400 and one small and inexpensively manufactured RM differential transformer/current sensor assembly 500.

It should be noted that voltage divider 609 to provide the voltage Vs across S 16a and N 16b lines is relatively unchanged other than possibly the values of the resistors. It should also be noted that the galvanic isolation interface 59 shown in the prior art smart meter 56 between the AFE 56a and the SoCh 56b in FIG. 2 is no longer required in the smart meter 656 of FIG. 6 because the RM current sensor assembly 400 provides the galvanic isolation the shunt resistor does not.

Thus, the method of manufacturing the RM differential current sensor 500 is not as complex as that for the RM current sensor assembly 400. The same considerations apply to configuring the circuit to achieve a target proportionality that reduces the size of the core 510 of the toroid, and reduces the current to be sensed to a range for which the differential current transformer 550 can operate over the substantially linear portion of its operating range, but because it operates on differential currents that will be quite small, this should be easier to achieve. An initial calibration of the output range over the given range of the service current for each divider may be desirable at tooling.

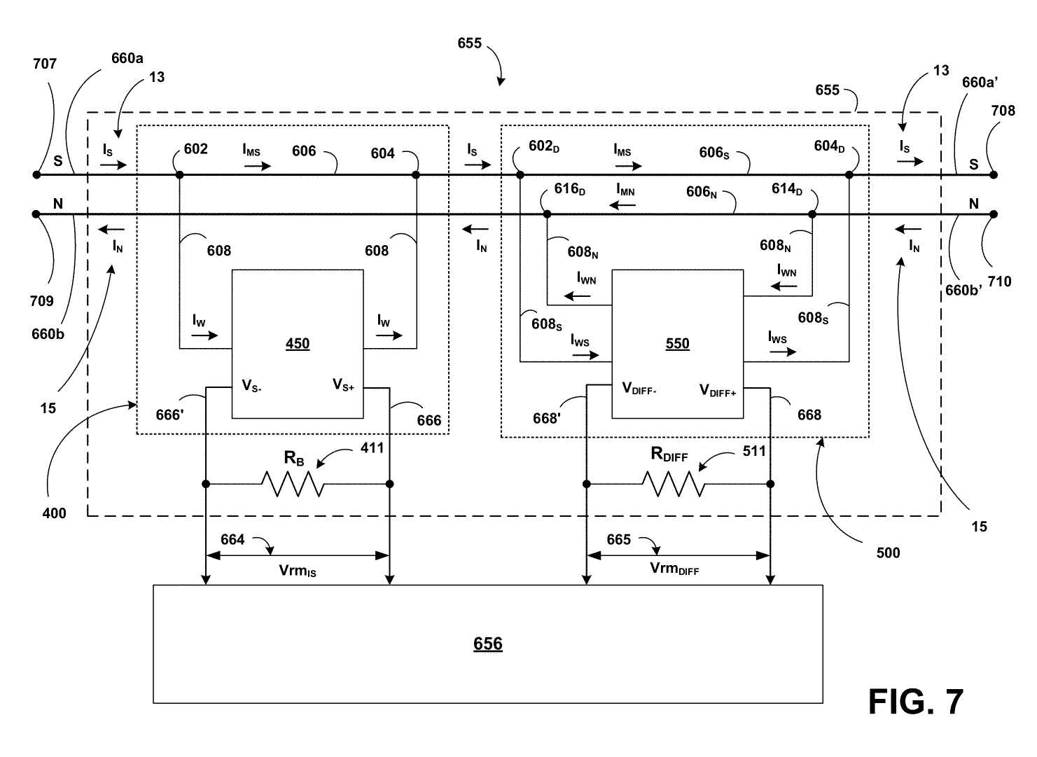

FIG. 7 illustrates a circuit block diagram of the RM sensor assembly 655, FIG. 6 without the voltage divider 609, which is largely the same as was described for the prior art. Those of skill in the art will appreciate that the toroidal current transformers 450 of the RM current sensor assemblies 400 and 550 of the RM differential current sensor assembly 500 are represented by general circuit blocks 400 and 500, and only the wired connections and burden sensors R_{B} 411 and R_{DIFF} 511 are shown for simplicity. RM sensor assembly 655 can be configured as a printed circuit board (PCB), to be conductively coupled in series with service line S 16a at edge connectors of the PCB at points 707, 708 through low impedance conductor 660a to 660a′. Likewise, RM sensor assembly 655 can be configured to be conductively coupled in series with service line N 16b at edge connectors of the PCB at points 709, 710 through low impedance conductor 660b to 660b′. The components of the RM sensor assembly 655 can be assembled on the printed circuit board PCB and all of the interconnect illustrated in FIG. 7 can be implemented as printed circuit board interconnect traces deposited on or below the surface of the PCB. Higher impedance conductors 608, 608_{N} and 608_{S} can be achieved as traces of higher resistive conductive elements such as resistors or even resistors in series with low impedance interconnect, or they can be flexible wires of higher impedance material that are insulated.

Those of skill in the art will appreciate that wires of higher resistance conductive material can be easily fed through their respective cores mounted on the PCB. However, the toroidal cores 410, 510 can also be partially embedded into the PC board, which would allow higher impedance traces to be routed through them. The secondary windings 409, 509 can be formed by wire hoops that can be coupled to traces on or within the PCB. It will be appreciated that there may be a number of ways that the RM current sensors assemblies 400, 500 of the invention can be physically implemented, but one important aspect of any such implementation is that the relatively high-impedance of the conductor used to form the secondary path(s) 408, 408_{S}, 408_{N} is (are) capable of being physically routable through the cores 410, 510 of the toroidal current sensors 450, 550. The conductors forming the secondary paths 408, 408_{S}, 408_{N} should be insulated or isolated to avoid inadvertent contact with other parts of the various assemblies.

The RM current sensor assembly 400, used for sensing the service current I_{S} 13 is magnetically coupled to higher impedance wire (or PCB trace) 608, which is conductively coupled to points 602, 604 to form the secondary path in parallel with main path 606 along conductor 660a, 660a′ to forth the current divider. Toroidal current transformer 450 is magnetically coupled to the secondary path formed by higher impedance conductor 608 passing as a winding through toroid 410. RM current sensor assembly 400, as described above, produces output Vrm_{IS} 664 across the burden resistor R_{B} 411 that is provided to smart current meter 656 by lines 666 and 666′. Vrm_{IS} 664 has a proportionality to the current I_{S} 13 that is partially established based on the impedance ratio between conductor 660a to 660a′ between interconnect nodes 602, 604 and wire 608, which defines the current ratio between the current I_{W} flowing in wire 608 and the current I_{MS} flowing in the main path 606, formed between the two attachment points 602, 604 along low impedance conductor 660a to 660a′. The proportionality is further partially established based on the turns ratio of the toroidal current transformer 450 and the value of the burden resistor R_{B} 411. Burden resistor R_{B} 411 can be implemented as a standard component mounted on the PCB once tooled, or it can be implemented as an interconnect resistive element on the PCB surface, that can be laser trimmed for additional accuracy.

Likewise, RM sensor 400_{S}, which is half of the RM differential current sensor assembly 500, FIG. 5, is also magnetically coupled to a secondary path formed by a second higher impedance conductor 608_{S} conductively coupled to service line S 16 through low impedance conductor 660a to 660a′. Higher impedance wire (or PCB trace) 608_{S} is conductively coupled to points 602, 604, to form the secondary path of the current divider in parallel with main path 606 along conductor 660a, 660a′. The fractional current flowing in wire 608_{S} is proportional to the current flowing in return (i.e. neutral) service line N 16a based on the ratio between the current I_{WS} flowing in wire 608_{S} and the current I_{MS} flowing in the main path 606_{S}, formed between the two points 602D, 604D along line S 16a. Toroidal differential current transformer 550 is magnetically coupled to the secondary path formed by higher impedance conductor 608_{S} passing as a winding through toroid 510.

RM sensor assembly 400_{N}, which is the second half of RM differential sensor assembly 500 (FIG. 5) is magnetically coupled to a secondary path formed by a third higher impedance conductor 608_{N}, which is conductively coupled to the return current service line N 16b, at circuit nodes 614_{D}, 616_{D}. Differential current transformer 550 is magnetically coupled to the secondary path formed by higher impedance conductor 608_{N} by passing it as a winding through toroid 510. I_{WS} and I_{WN} are fed or passed through core 510 in an anti-phase relationship with one another such that any difference or imbalance in the current flowing in those secondary paths will produce a magnetic flux that will generate a voltage Vrm_{DIFF} 665 across burden resistor R_{DIFF} 511 between output lines 565, 565′ that is proportional to the difference in currents.

RM differential current sensor assembly 500, as described above, produces output Vrm_{DIFF} 665 is provided to smart current meter 656 by lines 668 and 668′. Vrm_{DIFF} 665 has a proportionality to the current I_{N} 15 that is partially established based on the impedance ratios of the two current dividers, as well as the turns ratio of the toroidal differential current transformer 550 and the value of the burden resistor R_{DIFF} 511. As previously discussed, the precise ratios for each of the fractional currents will not have to match, as any initial imbalance between the currents in the absence of leakage can be normalized when establishing the value of the determined protection thresholds for leakage. However, it would not be difficult to subject the two current dividers to an initial calibration that calibrates the target proportionality for each current divider plus transformer to be substantially the same as previously described.

Thus, if the magnitudes of currents the service currents I_{S} and I_{N} are equal (and the current ratio of the two sensor assemblies 400_{S} and 400_{N} are substantially equal), the toroid will detect substantially zero differential current when no leakage is present. If leakage current (I_{LK} 70, FIGS. 2A, B) increases, I_{N} will decrease, and the imbalance will be reflected in the voltage across R_{DIFF} 511 (FIG. 5). Those of skill in the art will appreciate that a comparator circuit can be used to compare the voltage across R_{DIFF} 511, either in analog or digitized numerical values, to determine if a predetermined leakage threshold has been exceeded.

FIG. 8 represents the high-frequency pulses that appear riding on the service current waveform in the presence of a partial discharge from a parallel arcing fault. Partial discharge in the form of parallel arc faults is commonly observed when Hi Pot testing is performed to check the insulation of an electrical system. Whenever partial discharge is occurring, high frequency transient current pulses will appear in the load current and persist for nanoseconds to a few microseconds, then disappear and reappear repeatedly as the voltage sinewave goes through the zero crossing. The partial discharge happens near the peak voltage of the waveform both positive and negative. Partial discharge pulses are easy to measure using a prior art HFCT testing method, which gets its name from use of a “high frequency” current transducer clamped around the conducting cable being tested. The RM sensor current assembly would be used in lieu of this very expensive prior art sensor, one that can also be providing the sensed service current information to the smart meter for metering purposes.

Although far smaller and less expensive, the RM current sensor assembly 400 maintains the necessary high bandwidth required for detecting the small magnitude and short duration of these partial discharge events. The severity of the partial discharge is measured by timing the burst interval between the end of a burst and the beginning of the next burst. As the insulation breakdown worsens, the burst interval will shorten due to the breakdown happening at lower voltages. This burst interval will continue to shorten until a critical 2 millisecond duration of about 2 millisecond is reached. At this 2 millisecond point the discharge is very close to the zero crossing and will fail with a full blown discharge of electromagnetic waves that propagate away from the fault site in all directions. Detection of the high-frequency pulses identifies the existence of partial discharge. Bandpass filtering is used to eliminate interference from system noises that can interfere with detecting the presence of partial discharge.

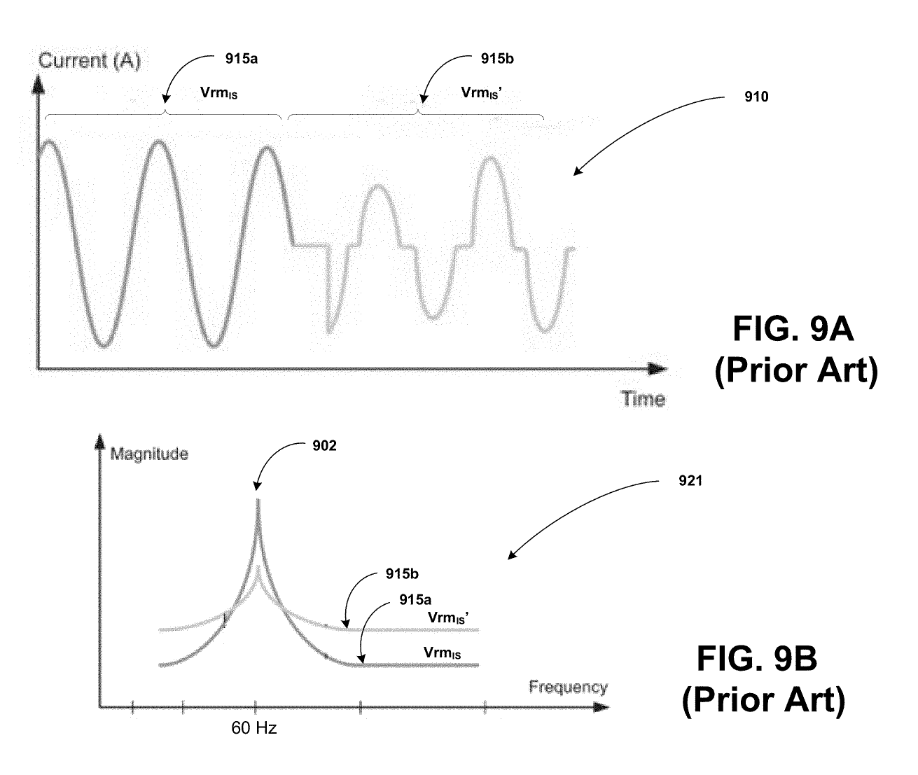

FIG. 9A illustrates a time-domain comparison between the service current I_{S} 13 waveform 910 where no series arcing is occurring 915a, and then when a series arc fault is present 915b. FIG. 9B illustrates the frequency domain representation of the current waveform 921 for the same two signal segments 915a, b. It will be appreciated that the magnitude for the service current I_{S} 13 at the fundamental frequency 902 in the presence of a series arc fault 915b is lower than that of the 915a where no fault is present. At higher harmonic frequencies, the opposite is true. As was previously discussed, these effects tend to decrease as the initially more intermittent nature of the series arc fault becomes more continuous by the carbonization of the insulation that bridges the gap over time. This should be useful in discriminating this type of fault over time. It is also a good reason why series faults should be detected at their incipiency before the characteristic signature becomes less easy to discern from other types of arcing currents which are expected.

There are many well-known techniques that can be used for detecting series arc faults, both in the time domain as well as in the frequency domain. In general, the problem requires the ability to extract features from the service current information that permit discrimination of those features that are the result of a true arc fault over other types of events that can also create similar features. These can include arcing cause by turning lights on and off, dimmer switches, appliances such as vacuum cleaners, electric mixers, etc. The details regarding these techniques are beyond the scope of this disclosure, but those of skill in the art will recognize that their successful implementation at the smart meter level will be greatly facilitated by the current sensor assembly 400.

One of the known techniques for identifying series arc faults from analyzing the sensed service current is to perform a Fast Fourier Transform (FFT) and identify increased magnitude of the current signal in the third harmonic. Thus, the sensed current output Vrm_{IS} 664 is sampled by the analog to digital converter of Analog Front End (AFE) 656a of the smart meter and then processed through a filter 940 to reduce the signal to the frequencies of interest, to reveal the features indicating the presence of a series arc fault.

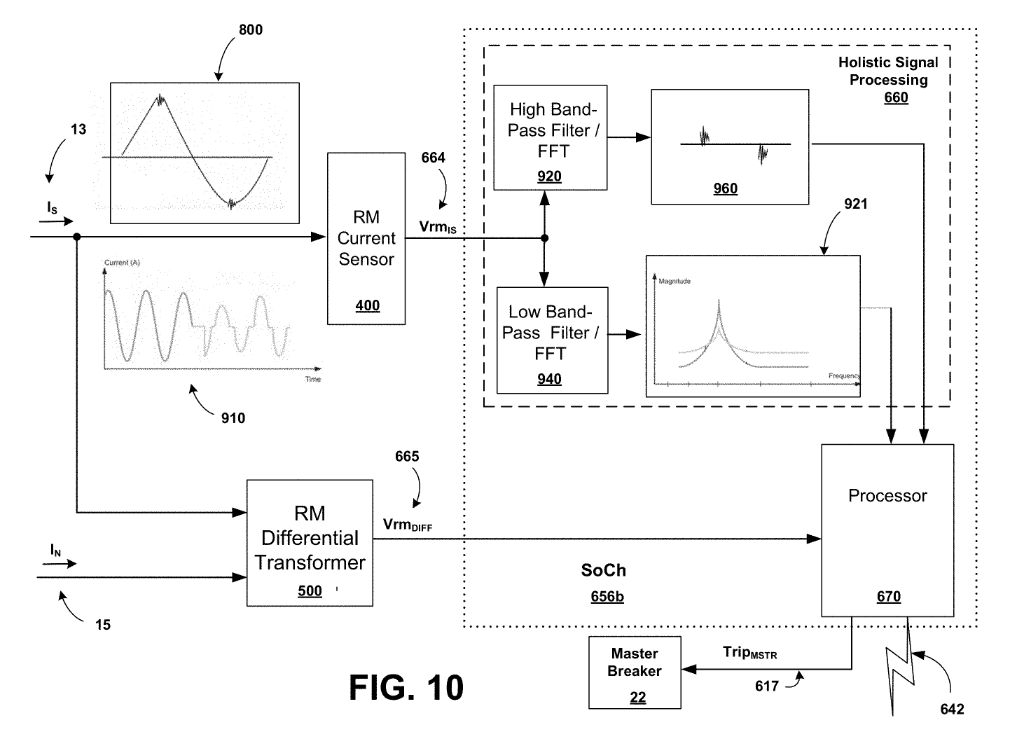

FIG. 10 shows a simplified block diagram for a holistic processing approach whereby the service current I_{S} 13 is sensed by RM current sensor assembly 400 to produce a continuous proportional output Vrm_{IS}, which is sampled by the AFE (656a, FIG. 6) and converted to digital values representing the service current I_{S} 13. Those values are processed by a High Band-Pass Filter or FFT algorithm at block 920 to isolate the features 810 as shown by block 960 that indicate the presence of parallel arc fault current as shown by waveform 800 of FIG. 8. Likewise, the samples of the service current I_{S} 13 are also fed to a low band pass filter/FFT block 940, by which to isolate the features that indicate the presence of a series arc fault current as shown by waveform 900 of FIG. 8.

A processor 670 can control the required digital signal processing and real time analysis of the samples of the sensed current output Vrm_{IS} 664, as well as any algorithmic processing by which to discriminate the arc faults from other phenomena. Processor 670 could be the same processor used to process the samples of Vrm_{IS} 664 for metering purposes, or it could be a dedicated processor for supporting the independent function of wellness. Processor 670 can be programmed to store and analyze the processed data in real time, and to monitor for the incipience of such faults on a continuous basis. The processor 670 can also be programmed to store data over time to permit observation of the features detected to aid in verifying that the data is in fact a fault and not manifestations of arcing or noise from switches and devices coupled to the branch circuit 25. Being able to observe progression of the fault for a time can aid in this discrimination to eliminate false positives and negatives. Observing the progression of a fault can also permit the smart meter to ramp up the urgency of alarms that can be shown visually in the form of lights or sound and/or messaging can be sent out over the network interface 642 respectively.

It will be appreciated that the digital signal processing system used for performing arc fault monitoring and detection, as well as current signature analysis and cumulative leakage could be performed by the existing processing resources already resident in the smart meter, or these resources could be dedicated for this performance to avoid interfering with the smart meter's metering functions.

Isolating the physical location of detected arc faults requires a technician to come to a building and use equipment to listen for the electromagnetic waves that propagate away from the fault site so that the wiring can be replaced or repaired. By monitoring for the incipiency of arc faults such as partial discharge, an occupant or owner of a premises can be alerted early on to the potential fire hazard and the need for an inspection by a technician. Such inspections would be far more likely to occur when initiated based on an actual positive detection of partial discharge occurring in the premises.

As part of holistic approach, RM differential current sensor assembly 500 also detects cumulative ground fault leakage current from the entire branch circuit 25, which can also be used by processor 670 as an additional condition for which to monitor the health of the branch circuit 25 loads coupled thereto, at the service current level. In addition, wellness of appliances can also be monitored using known current signature analysis techniques that can be monitored by the smart meter 670 or a dedicated signal processing system that dedicated resources specifically to the required analysis of the sensed current output.

Those of skill in the art will recognize that current signature analysis techniques used to detect operational deficiencies in motors and pumps are performed similarly to monitoring for the detection of arc faults. The sensed current output is sampled and converted to a digital representation of the sampled magnitude. The digital samples are used to establish an representation of the sensed current by which to reveal and extract features that uniquely indicate the presence of operational problems. Detection algorithms are then used to discriminate the types of faults based on known signatures of those features unique to the presence of a specific type of operational fault. These techniques are well known, and the RM current sensor assembly supports the easy implementation of these known techniques such that they can be integrated into the functions already being performed by a smart meter.

For example, harmonic signature analysis of the consumer's current can be performed to detect arc faults manifesting as series and parallel leakage currents within the electric branch circuit and surrounding insulation. A smart meter employing the RM current sensor assemblies of the invention can cost-effectively monitor the operational health of insulation in the wiring to detect the potential for, and ultimately to pre-empt, building fires by detecting such faults at their incipiency. The operational integrity of various load components such as motors for air conditioning, large appliances, and industrial installations can also be monitored using this signature analysis to determine declining performance of such devices to trigger their repair or replacement.

A smart meter is the perfect device by which to integrate the software and digital signal processing of the supplied current information to permit overall wellness analysis of the electrical branch circuit and devices of all premises. The RM current sensor assembly 400 provides a cost effective means by which to provide the sensed service current information at the service current level from which to glean and process this information.

What is claimed is:

1. A ratio metric (RM) sensor assembly for sensing a service current being drawn from an electrical service through a service line by an electric branch circuit to support real-time monitoring of the electrical integrity of the electrical branch circuit, the RM sensor assembly comprising:
an RM current sensor assembly comprising:
a current divider formed of:
a low impedance conductor, the low impedance conductor configured to be conductively coupled in series with the service line carrying the service current to the electrical branch, and
a higher impedance conductor coupled at two points along the lower impedance conductor; and
a current transformer including:
a toroidal core through which the higher impedance conductor is fed as a primary winding; and
a secondary formed of one or more windings about the core and coupled to a burden resistor that is coupled to the secondary,
wherein the RM current sensor assembly is configured to produce a sensed current output across the burden resistor, the sensed current output having a predetermined operational range of magnitude that is proportionally related to the sensed service current over the predetermined operational range of the service current, and
wherein the sensed current output is coupled to a smart meter, the smart meter using the sensed current output to monitor for the presence of an arc fault in the electrical branch circuit.

2. The RM sensor assembly of claim 1, wherein the arc fault is a series arc fault.

3. The RM sensor assembly of claim 1, wherein the arc fault is a parallel arc fault.

4. The RM sensor assembly of claim 1, wherein an electronic message is sent by the smart meter over a network to notify the service when the presence of the arc fault has been detected.

5. The RM sensor assembly of claim 1, further comprising a differential current sensor assembly including:
a first current divider formed of a low impedance conductor configured to be coupled in series with the service line, and a first higher impedance conductor coupled at two points along the lower impedance conductor;
a second current divider formed of a low impedance conductor configured to be coupled in series with a neutral line by which the service current is returned to the service, and a second higher impedance conductor coupled at two points along the lower impedance conductor; and
a differential current transformer including:
a toroidal core through which the first and second higher impedance conductors are fed as primary windings; and
a secondary formed of one or more windings about the core and coupled to a burden resistor that is coupled to the secondary,
wherein the RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit, and
wherein the sensed differential current output is coupled to the smart meter, the smart meter using the sensed differential current output to detect cumulative leakage current to ground in the electrical branch circuit.

6. The RM sensor assembly of claim 5, wherein an electronic message is sent by the smart meter over a network to notify the service of the cumulative leakage that has been detected.

7. The RM sensor assembly of claim 1, wherein the sensed current output is used to support current signature analysis to monitor operational integrity of one or more load devices coupled to the electrical branch circuit.

8. The RM sensor assembly of claim 1, wherein the sensed current output is also used by the smart meter to, within a predetermined degree of accuracy, support a determination of the power consumption based on an aggregation of the service current drawn by the electrical branch circuit over a predetermined period of time.

9. A smart meter for analyzing the service current drawn through a service line from an electrical service to provide real-time monitoring of the electrical integrity of the electrical branch circuit and one or more load devices coupled thereto, the smart meter comprising:
an RM sensor assembly coupled in series with the service line, the RM current sensor assembly including:
at least one RM current sensor assembly including:
a current divider formed of:
a low impedance conductor, the low impedance conductor configured to be conductively coupled in series with the service line carrying the service current to the electrical branch, and
a higher impedance conductor coupled at two points along the lower impedance conductor; and
a current transformer including:
a toroidal core through which the higher impedance conductor is fed as a primary winding; and
a secondary formed of one or more windings about the core and coupled to a burden resistor that is coupled to the secondary;
wherein the RM current sensor assembly is configured to produce a sensed current output across the burden resistor, the sensed current output having a predetermined operational range of magnitude that is proportionally related to the sensed service current over the predetermined operational range of the service current, and
an analog front (AFE) configured to receive the sensed current output, the AFE configured to sample the sensed current output at a predetermined rate and convert the samples into digital values; and
a processor system for monitoring the sensed output current for the presence of arc faults in the electrical branch circuit, the processor system extracting features from the digital values of the sensed current output that indicates the presence of an arc fault.

10. The smart meter of claim 9, wherein the arc fault is a series arc fault.

11. The smart meter of claim 9, wherein the arc fault is a parallel arc fault.

12. The smart meter of claim 9, wherein the processing system transmits an electronic message over a network to notify the service that the presence of the arc fault has been detected.

13. The smart meter of claim 9, wherein the RM sensor assembly further comprises a differential current sensor assembly including:
a first current divider formed of a low impedance conductor configured to be coupled in series with the service line, and a first higher impedance conductor coupled at two points along the lower impedance conductor;
a second current divider formed of a low impedance conductor configured to be coupled in series with a neutral line by which the service current is returned to the service, and a second higher impedance conductor coupled at two points along the lower impedance conductor; and
a differential current transformer including:
a toroidal core through which the first and second higher impedance conductors are fed as primary windings; and
a toroidal core through which the first and second higher impedance conductors are fed as primary windings,
wherein the RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit,
wherein the sensed differential current output is coupled to the AFE, the AFE configured to sample the sensed current output at a predetermined rate and convert the samples into digital values, and
wherein the processor system uses the digital sampled of the sensed differential current output to detect cumulative leakage current to ground in the electrical branch circuit.

14. The smart meter of claim 13, wherein an electronic message is sent by the processing system over a network to notify the service of the degree of cumulative leakage that has been detected.

15. The smart meter of claim 9, wherein the digital samples of the sensed current output are used to support current signature analysis to detect faults in the one or more load devices.

16. The smart meter of claim 9, wherein the digital samples of the sensed current output are also used to determine power consumption within a predetermined degree of accuracy based on a cumulative service current drawn by the electrical branch circuit over a predetermined period of time.
